(19) United States
(12) Patent Application Publication
(10) Pub. No.: US 2012/0217523 A1
(43) Pub. Date: Aug. 30, 2012

(54) LIGHT EMITTING DIODE PACKAGING STRUCTURE

(75) Inventors: WEI CHANG, NEW TAIPEI CITY (TW); HUAN-YING LU, NEW TAIPEI CITY (TW); SHIH-CHAO SHEN, NEW TAIPEI CITY (TW)

(73) Assignee: UNITY OPTO TECHNOLOGY CO., LTD., NEW TAIPEI CITY (TW)

(21) Appl. No.: 13/184,606

(22) Filed: Jul. 18, 2011

(30) Foreign Application Priority Data
Feb. 25, 2011 (TW) 100203451

(51) Int. Cl. H01L 33/60

(52) U.S. Cl. 257/98; 257/E33.072

(57) ABSTRACT

A light emitting diode (LED) packaging structure comprises a base, a LED chip and a packaging colloid. The LED chip is disposed in the base. The packaging colloid comprises a first optical resin material and at least one second optical resin material. The first optical resin material is transparent and packages the LED chip. The second optical resin material is disposed to a side of the first optical resin material. The second optical resin material is doped with a second fluorescent-powder. By disposing multilayered second optical resin materials, the fluorescent-powder is far from the LED chip to prevent the fluorescent-powder from being heated to cause light attenuation, thereby extending the service life of the LED chip.

### CROSS-REFERENCE TO RELATED APPLICATIONS

This non-provisional application claims priority under 35 U.S.C. §119(a) on Patent Application No(s). 100203451 filed in Taiwan, R.O.C. on Feb. 25, 2011, the entire contents of which are hereby incorporated by reference.

### BACKGROUND OF THE INVENTION

1. Field of the Invention

The present invention relates to a packaging structure, and more particularly to the packaging structure for light emitting diode.

2. Description of the Related Art

Light emitting diodes (LED) are taken as light source system made of utilizing solid-state materials such as a semiconductor and different from conventional light sources such as incandescent lamps, which must be operated under vacuum condition or filled with fewer specific gas, or discharge lamps with various gases. Comparing with the conventional light sources, a white LED light source has more advantages of low power consumption, small volume, fast reaction speed, high efficiency, environmental protection and capable of planar packaged and has 60 years of service life in respect to energy saving and is 100 folds of a conventional light bulb. The energy consumed by the white LED is merely 10% of the conventional light bulb.

Since high power and high brightness LEDs are successfully developed, the light emitting efficiency of the white light LED has been achieved above 60 to 80 lm/W and is further achieved more than 100 lm/W by comparing with the conventional incandescent lamp with 60 lm/W light emitting efficiency. The LED is still continuously researched and advanced. When the white light LED with 100 lm/W light emitting efficiency can be commercialized in mass markets, the incandescent lamp and a fluorescent lamp can be replaced with the white light LED to form a main stream of illumination light source for next generation.

Generally, if the LED is used to make the white light LED for illumination, it must apply a technique of light color combination so as to achieve a goal of obtaining white light. In the conventional technique of light color combination capable of being feasible, fluorescent materials are utilized to mix or convert light colors to form a kind of a manner that is the most convenient and saved with cost. The white light LED made of applying fluorescent materials is so-called PC-white-LED (phosphor-converted white LED).

After LED dies are completely produced, it must be adhered to a lead frame and performed with process flows such as die bonding, solidifying, wire bonding, resin encapsulation, baking, cutting, testing and packing to form different types of LED components through die package.

A main packaging of a white light LED is that a surface of a blue light LED with 450 to 460 wavelengths is coated with yttrium aluminum garnet (YAG) that is a fluorescent material which is most frequently seen and has the simplest power loop structure and the lowest cost. When a YAG fluorescent material is excited, it is mixed with color to form white light after generating 550 to 560 nm wavelengths and absorbing light with 450 to 470 nm wavelengths. Since its luminescence spectrum is quite wide, the tolerance degree for wavelength error is also relatively enhanced such that when packaging industries produce white light LEDs, the production yield can be improved to further reduce costs.

A conventional white light LED 1 is that a blue light LED 11 is disposed to a bottom of a reflector 12, and YAG fluorescent powder 13 then is mixed with an optical resin material (e.g. epoxy resin or silicon resin) to form an optical resin layer 14. After the optical resin layer 14 is solidified and formed, a packaging process then is almost done as shown in FIG. 1. Although the production is fast, it is difficult to control the thickness of the optical resin material 14 containing the fluorescent powder 13 onto the blue light LED 11, and the deposition effect will be generated after mixing the fluorescent powder 13 for a while. Consequently, the concentration of the fluorescent powder 13 is lower at an upper layer, and higher at the lower layer. It does not only cause non-uniform thicknesses and iridescence, but also generates yellow hue and halation during the light emitting process. While using high power LED, the concentration of the fluorescent powder at the lower layer is high and is in contact with a LED chip, and the heat dissipation of the fluorescent powder is not well under high temperature and heat to cause fast light attenuation so that the light emitting efficiency is reduced, and the attrition rate is increased to reduce the product yield.

To overcome the foregoing shortcomings of packaging conventional white light LED fluorescent powder, the industries use processes such as spin coating, sputtering coating or n-shaped coating. However, the foregoing manners still have defects as the following:

1: Although spin coating could reduce the thickness of the fluorescent powder layer, it has phenomenon in which an inner layer is thin while an external layer is thick. Moreover, since the influence is generated among each fluorescent powder layer, it may not be separated from a substrate.

2: Although sputtering coating could achieve an effect of uniformly distributing the fluorescent powder layer, the expense of targets is too high. Consequently, the production cost stays at a high level and is difficult to compete against others.

3: Although n-shaped coating could achieve identical thickness for the fluorescent powder layer, it may not reduce the phenomenon of seriously depositing the fluorescent powder.

### SUMMARY OF THE INVENTION

In view of the shortcomings of the prior art, the inventor(s) of the present invention based on years of experience in the related industry to conduct extensive researches and experiments, and finally developed a LED packaging structure as a primary objective, and more particularly to multilayered optical resin materials doped with fluorescent-powder to package a LED chip to prevent the fluorescent-powder from extremely closing to the LED chip so that light attenuation can be avoid, and a service life can be extended.

To achieve the foregoing objective, the LED packaging structure comprises a base, a LED chip and a packaging colloid. The LED chip is disposed in the base. The packaging colloid comprises a first optical resin material and at least one second optical resin material. The first optical resin material encapsulates the first LED chip. The second optical resin material is disposed to a side of the second optical resin material, and the second optical resin material is doped with a second fluorescent-powder.

The first optical resin material is doped with a first fluorescent-powder, and a doping concentration of the first fluorescent-powder is lower than the doping concentration of the second fluorescent-powder.

A concentration of the first fluorescent-powder doped in the first optical resin material is toward a direction of the LED chip to sequentially show a variation of intermediate-concentration, high-concentration and low-concentration, and a concentration of the second fluorescent-powder doped in the second optical resin material is toward a direction of the LED chip to sequentially a variation of intermediate-concentration, high-concentration and low-concentration.

The LED packaging structure has a plurality of second optical resin materials, and a concentration of the second fluorescent-powder doped in each second optical resin material is respectively toward a direction of the LED chip from the second optical resin materials to sequentially show a variation of intermediate-concentration, high-concentration and low-concentration, so that a circulation variation of intermediate-concentration, high-concentration and low-concentration is shown toward a direction of the LED chip from an external surface side of the whole packaging colloid.

When the LED chip is used for 1600 hours, an illumination intensity of the LED chip remains 98% illumination intensity by comparing with a no-use condition.

When a thickness of the first optical resin material is below 0.3 mm, a brightness of the LED packaging structure is decreased to 3%.

A thickness of the first optical resin material is below 0.5 mm, a brightness of the LED packaging structure is decreased to 7 to 10%.

The base is a LED reflector.

The first fluorescent-powder and the second fluorescent-powder are yttrium aluminum garnet (YAG) fluorescent-powder (Y₃Al₅O₁₂) and derivatives. The first fluorescent-powder and the second fluorescent-powder are terbium aluminum garnet (TAG) fluorescent-powder (Tb₃Al₅O₁₂) and derivatives.

The first fluorescent-powder and the second fluorescent-powder are CASN-based, fluorescent-powder (CaAlSiN₃:Eu) and derivatives.

The first fluorescent-powder and the second fluorescent-powder are silicate fluorescent-powder and derivatives.

### BRIEF DESCRIPTION OF THE DRAWINGS

FIG. 1 is a schematic diagram of a conventional LED packaging structure;

FIG. 2 is a schematic diagram of a LED packaging structure in accordance to a first embodiment of the present invention;

FIG. 3 is a schematic diagram of an optical path of a LED packaging structure in accordance to a first embodiment of the present invention;

FIG. 4 is a schematic diagram of a LED packaging structure in accordance to a second embodiment of the present invention;

FIG. 5 is a schematic diagram of a LED packaging structure in accordance to a third embodiment of the present invention; and

FIG. 6 is a distribution diagram of a polygonal line of an illumination intensity versus time of a LED packaging structure.

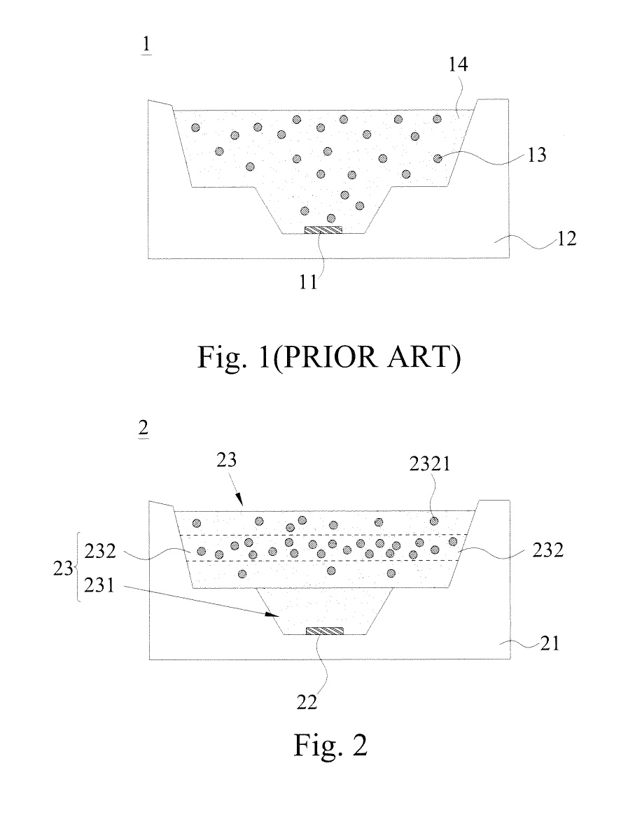

### DETAILED DESCRIPTION OF THE PREFERRED EMBODIMENTS

The foregoing and other technical characteristics of the present invention will become apparent with the detailed description of the preferred embodiments and the illustration of the related drawings.

With reference to FIG. 2 for a schematic diagram of a light emitting diode (LED) packaging structure in accordance with a first embodiment of the invention is depicted. The LED packaging structure 2 comprises a base 21, a LED chip 22 and a packaging colloid 23.

In the embodiment, the base 21 is a LED reflector. The LED chip 22 is a blue light LED and can emit about 450-460 nm wavelengths and disposed to a bottom of the base 21. The packing colloid 23 comprises a first optical resin material 231 and a second optical resin material 232. The first optical resin 231 can be epoxy resin or silicon resin and packages the LED chip 22. The second optical resin material 232 can be epoxy resin or silicon resin and is disposed to a side of the first optical resin material 231 and fully fills with a containing space of the base. The second optical resin material 232 is doped with a second fluorescent-powder 2321, wherein the concentration distribution of the second fluorescent-powder 2321 doped in the second optical resin material 232 is respectively toward the direction of the LED chip 22 from the second optical resin materials 232 to show variation of intermediate-concentration, high-concentration and low-concentration. In the embodiment, the second fluorescent-powder 2321 can be yttrium aluminum garnet (YAG) fluorescent-powder (Y₃Al₅O₁₂) and derivatives. Alternatively, it can be terbium aluminum garnet (TAG) fluorescent-powder (Tb₃Al₅O₁₂) and derivatives, or CASN-based fluorescent-powder (CaAlSiN3: Eu) and derivatives, or silicate fluorescent-powder and derivatives.

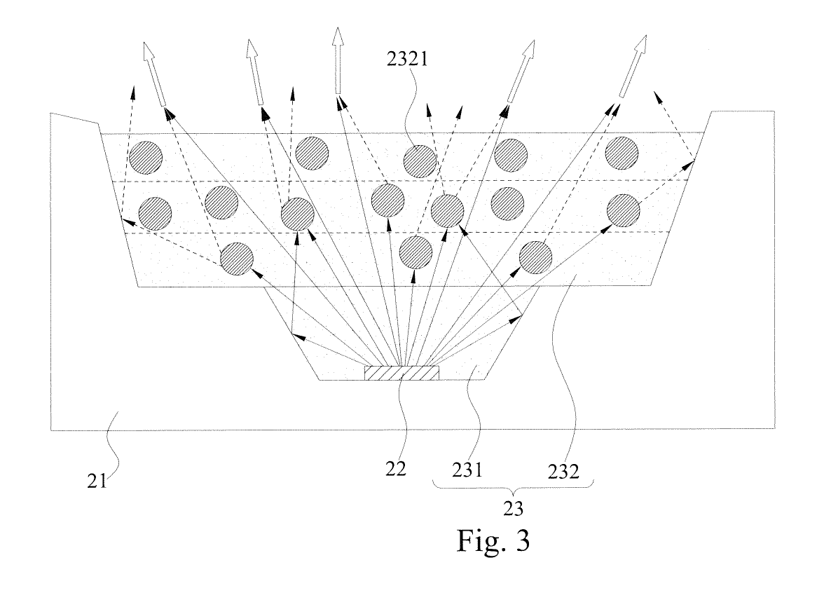

With reference to FIG. 3 for a schematic diagram of an optical path of a LED packaging structure in accordance with a first embodiment of the invention is depicted. While driving the LED packaging structure to allow the LED chip 22 to emit light, the second fluorescent-powder 2321 is excited to generate yellow light with about 550 to 560 nm wavelengths. After a blue light generated by the LED chip 22 is mixed with the yellow light, white light is produced. Alternatively, the white light can also be produced by exciting green and red fluorescent powder with about 515 to 545 nm and 620-650 nm wavelengths respectively, and mixed with a blue light generated by a blue light LED chip. Since the first optical resin material 231 near the LED chip 22 is not doped with any fluorescent-powder, the situation of reducing efficiency and product yield rate resulting from light attenuation caused by worse heat dissipation due to the fluorescent-powder that is too close to the LED chip 22 can be prevented, thereby decreasing the attenuation rate of illumination intensity and extending the service life.

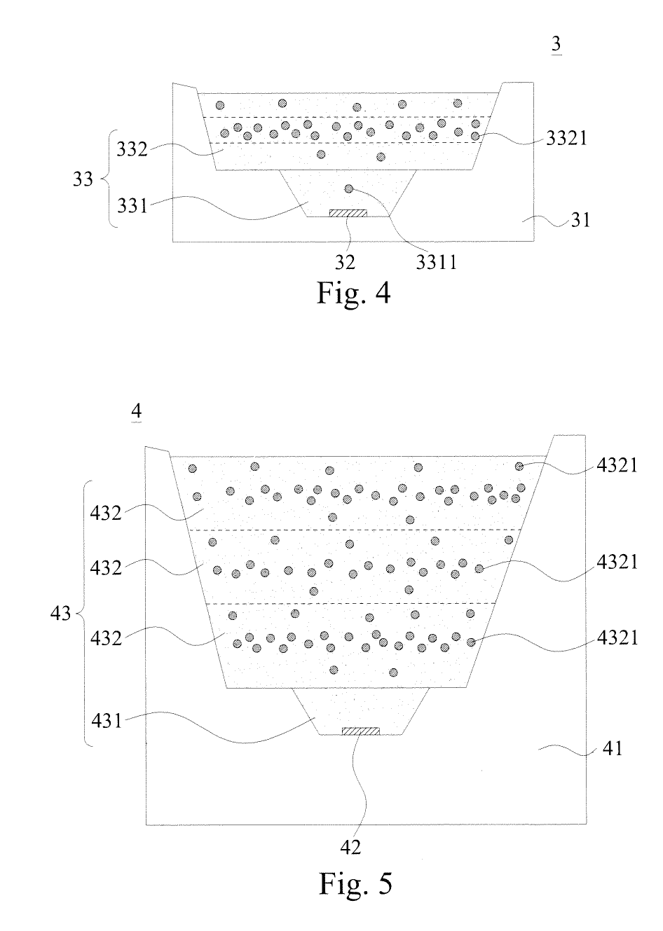

With reference to FIG. 4 for a schematic diagram of a LED packaging structure in accordance with a second embodiment of the invention is depicted. In the figure, the LED packaging structure 3 comprises a base 31, a LED chip 32 and a packaging colloid 33. The packaging colloid 33 comprises a first optical resin material 331 and a second optical resin material 332. The second optical resin material 332 is doped with a second fluorescent-powder 3321. In the embodiment, the structures and functions of the base 31, the LED chip 32 and the second optical resin material 332 are the same as the first embodiment, and there is no need to describe herein. The difference between the embodiment and the first embodiment is that the first optical resin material 331 is further doped with a first fluorescent-powder 3311 to enhance the brightness. To prevent the fluorescent-powder from being heated to cause light attenuation, an average doping concentration of the first fluorescent powder 3311 is lower than the second fluorescent-powder 3321. In addition, the concentration distribution of the first fluorescent-powder 3311 doped in the first optical resin material 331 is respectively toward the direction of the LED chip 32 to sequentially show the variation of intermediate-concentration, high-concentration and low-concentration. Further, the thickness of the first optical resin material 331 can be varied in accordance with design demands. When the thickness is thicker, the attenuation rate of brightness is higher. When the thickness of the first optical resin material 331 is below 0.3 mm, the brightness of the LED packaging structure 3 is decreased to about 3%. When the thickness of the first optical resin material 331 is about 0.5 mm, the brightness of the LED packaging structure 3 is decreased to about 7 to 10%.

With reference to FIG. 5 for a schematic diagram of a LED packaging structure in accordance with a third embodiment of the invention is depicted. The LED packaging structure 4 comprises a base 41, a LED chip 42 and a packaging colloid 43. The packaging colloid 43 comprises a first optical resin material 431. In the embodiment, the structures and functions of the base 41, the LED chip 42 and the first optical resin material 431 are the same as the first embodiment, and there is no need to describe herein. The difference between the embodiment and the first embodiment is that the packaging colloid 43 further has a plurality of second optical resin materials 432. The distribution of the second optical resin material 4321 doped in each second optical resin material 432 is respectively toward the direction of the LED chip 42 from the second optical resin materials 432, and sequentially show the variation of intermediate-concentration, high-concentration and low-concentration. Therefore, a circulation variation of intermediate concentration, high concentration and low concentration is shown toward a direction of the LED chip 42 from an external surface side of the whole packaging colloid 43. Accordingly, the fluorescent-powder can be uniformly distributed in the packaging colloid 43 so that the color temperature can be uniformly distributed while emitting light.

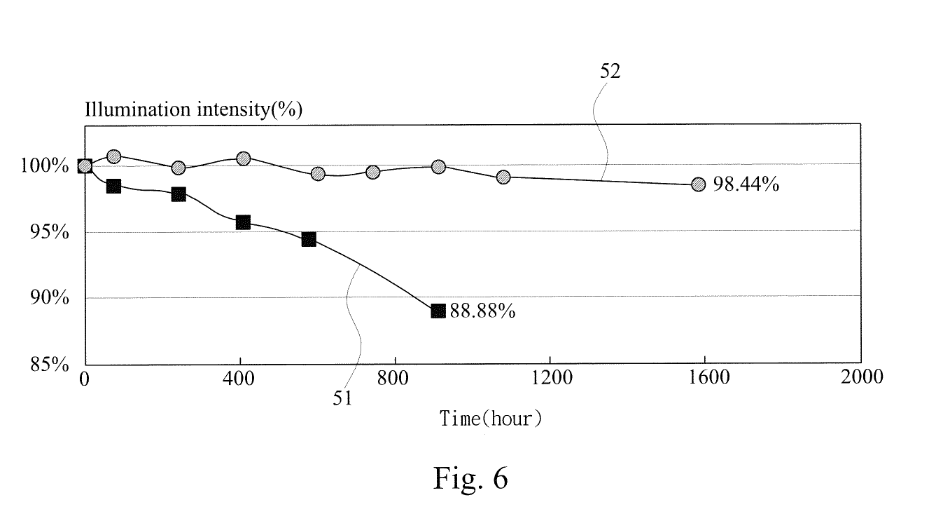

To clearly understand the effect caused by the multilayered optical resin material packaging LEDs, with reference to FIG. 6 for a polygonal line diagram of illumination intensity-time between a LED packaging structure of the invention and a prior art is depicted. A polygonal line 51 of distribution of illumination intensity-time generated by a conventional white light LED is observed. After using about 400 hours, 800 hours and 900 hours, the illumination intensity remains about 95%, 92% and 88% respectively by comparing with no-use condition, and the light attenuation is getting worse, and it is unable to be taken in an illuminating that must be operated long time. A polygonal line 52 of distribution of illumination intensity-time generated by the LED packaging structure of the invention is observed. Before achieving 1100 hours, the illumination intensity does not have any significant attenuation. While achieving 1600 hours, it remains 98% illumination intensity by comparing with no-use condition, thereby greatly improving the service life.

The efficacy of the LED packaging structure of the invention is that the LED packaging structure is equipped with a plurality of layered optical resin materials so that the optical resin material near the LED chip is not doped or is doped with fewer fluorescent-powder to prevent the fluorescent-powder from being heated to cause light attenuation, thereby extending the service life.

One efficacy of the LED packaging structure of the invention is that the LED packaging structure is equipped with a plurality of layered optical resin materials. Each optical resin material is doped with fluorescent-powder so that the fluorescent-powder can be uniformly distributed in the optical resin material to uniform the color temperature.

The invention improves over the prior art and complies with patent application requirements, and thus is duly filed for patent application. While the invention has been described by device of specific embodiments, numerous modifications and variations could be made thereto by those generally skilled in the art without departing from the scope and spirit of the invention set forth in the claims.

What is claimed is:

1. A light emitting diode (LED) packaging structure comprising:
a base;
a LED chip disposed in the base; and
a packaging colloid, the packaging colloid including:
a first optical resin material encapsulating the LED chip; and
at least one second optical resin material doped with a second fluorescent-powder disposed to a side of the first optical resin material.

2. The light emitting diode packaging structure as recited in claim 1, wherein the first optical resin material is doped with a first fluorescent-powder, and a doping concentration of the first fluorescent-powder is lower than a doping concentration of the second fluorescent-powder.

3. The light emitting diode packaging structure as recited in claim 2, wherein a concentration of the first fluorescent-powder doped in the first optical resin material is toward a direction of the LED chip to sequentially show a variation of intermediate-concentration, high-concentration and low-concentration, and a concentration of the second fluorescent-powder in the second optical resin material is toward a direction of the LED chip to sequentially a variation of intermediate-concentration, high-concentration and low-concentration.

4. The light emitting diode packaging structure as recited in claim 1, wherein the LED packaging structure has a plurality of second optical resin materials, and a concentration of the second fluorescent-powder doped in each second optical resin material is respectively toward a direction of the LED chip from the second optical resin materials to sequentially show a variation of intermediate-concentration, high-concentration and low-concentration so that a circulation variation of intermediate-concentration, high-concentration and low-concentration is shown toward a direction of the LED chip from an external surface side of the whole packaging colloid.

5. The light emitting diode packaging structure as recited in claim 1, wherein when the LED chip is used for 1600 hours, an illumination intensity of the LED chip remains 98% illumination intensity by comparing with a no-use condition.

6. The light emitting diode packaging structure as recited in claim 1, wherein when a thickness of the first optical resin material is below 0.3 mm, a brightness of the LED packaging structure is decreased to 3%.

7. The light emitting diode packaging structure as recited in claim 1, wherein a thickness of the first optical resin material is below 0.5 mm, a brightness of the LED packaging structure is decreased to 7 to 10%.

8. The light emitting diode packaging structure as recited in claim 1, wherein the base is a LED reflector.

9. The light emitting diode packaging structure as recited in claim 2, wherein the first fluorescent-powder and the second fluorescent-powder are yttrium aluminum garnet (YAG) fluorescent-powder (Y₃AL₅O₁₂) and derivatives.

10. The light emitting diode packaging structure as recited in claim 2, wherein the first fluorescent-powder and the second fluorescent-powder are terbium aluminum garnet (TAG) fluorescent-powder (Tb₃Al₅O₁₂) and derivatives.

11. The light emitting diode packaging structure as recited in claim 2, wherein the first fluorescent-powder and the second fluorescent-powder are CASN-based fluorescent-powder (CaAlSiN₃:Eu) and derivatives.

12. The light emitting diode packaging structure as recited in claim 2, wherein the first fluorescent-powder and the second fluorescent-powder are silicate fluorescent-powder and derivatives.
